(19) United States
(12) Patent Application Publication
(10) Pub. No.: US 2026/0068557 A1
(43) Pub. Date: Mar. 5, 2026

(54) METHOD FOR MANUFACTURING SEMICONDUCTOR DEVICE WITH REDUCED INTERFACIAL LAYER THICKNESS

(71) Applicant: TAIWAN SEMICONDUCTOR MANUFACTURING COMPANY, LTD., Hsinchu (TW)

(72) Inventors: Shen-Yang LEE, Hsinchu (TW); Hsiang-Pi CHANG, Hsinchu (TW); Hsu-Kai CHANG, Hsinchu (TW); Chun-Fu LU, Hsinchu (TW); Huang-Lin CHAO, Hsinchu (TW); Kenichi SANO, Hsinchu (TW); Pinyen LIN, Hsinchu (TW)

(73) Assignee: TAIWAN SEMICONDUCTOR MANUFACTURING COMPANY, LTD., Hsinchu (TW)

(21) Appl. No.: 18/821,914

(22) Filed: Aug. 30, 2024

(51) Int. Cl. H01L 21/02; H01L 21/311; H01L 29/06; H01L 29/423; H01L 29/66; H01L 29/775; H01L 29/786

(52) U.S. Cl. CPC H01L 21/02164; H10D 30/014; H10D 30/43; H10D 30/6735; H10D 30/6757; H10D 62/121

(57) ABSTRACT

A method for manufacturing a semiconductor device includes: forming a semiconductor structure on a semiconductor substrate, the semiconductor structure including first and second source/drain regions disposed on the semiconductor substrate in a first direction and spaced apart from each other in a second direction transverse to the first direction, and a plurality of channel features disposed between and connected to the first and second source/drain regions and spaced apart from one another in the first direction; forming an interfacial material layer to cover the channel features; forming a metal oxide layer on the interfacial material layer; converting a portion of the interfacial material layer into a metal silicate layer so as to form a plurality of interfacial features respectively covering the channel features, the metal silicate layer being formed between the metal oxide layer and the interfacial features; and removing the metal oxide layer and the metal silicate layer.

### BACKGROUND

In recent decades, the semiconductor industry is devoted to developing high performance integrated circuit (IC) chips. An IC chip may include a plurality of semiconductor devices (for example, nanosheet field-effect transistors, etc.). In order to increase functional density (i.e., the number of semiconductor devices per chip area) and the economic benefit of an IC chip, a continual reduction in minimum feature sizes of the IC chip is required. However, the scaling down of the feature sizes of the IC chip may result in quality issues (for example, an interfacial layer disposed between a silicon channel and a gate dielectric has more defects due to worsening quality thereof). These quality issues may adversely affect device performance of the semiconductor devices in the IC chip and production yield of the IC chip.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor device in accordance with some embodiments.

FIGS. 2 to 10B are schematic views illustrating some intermediate stages of the method as depicted in FIG. 1 in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “over,” “upper,” “lower,” “uppermost,” and the like, may be used herein for case of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be noted that the element(s) or feature(s) are exaggeratedly shown in the figures for the purposed of convenient illustration and are not in scale.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

The term “source/drain region(s)” may refer to a source or a drain, individually or collectively dependent upon the context.

An integrated circuit (IC) chip, which includes a plurality of semiconductor devices (e.g., nanosheet field-effect transistors, etc.), is an important component in electrical products. A continual reduction in minimum feature sizes of an IC chip is a trend in the semiconductor industry because functional density of the IC chip (i.e., the number of semiconductor devices per chip area) can be increased and device performance of the semiconductor devices can be improved. For example, as the size of an IC chip shrinks, an equivalent oxide thickness (EOT) of each of the semiconductor devices is reduced, and a driving current of the each of the semiconductor devices increases proportionally, which is conducive to improving the device performance of the semiconductor devices.

However, some issues may occur with the scaling down of the feature sizes of the IC chip. For example, a common method for reducing EOT (e.g., reducing a time period of a wet process used in formation of an interfacial layer (e.g., made of silicon oxide)) may cause more defects (e.g., oxygen vacancies), a poor uniformity, and a higher trap density (an increase in trap-assisted tunneling effect) of the interfacial layer. In this case, electrons in a silicon channel that is covered by the interfacial layer may migrate to a metal gate that is disposed on the interfacial layer opposite to the silicon channel through the defects of the interfacial layer, resulting in a higher leakage current and a degradation in chip performance of the IC chip or the device performance of the semiconductor devices. For another example, a process of forming the metal gate (e.g., made of aluminum or titanium) and/or a silicon cap layer disposed on the metal gate can attract oxygen atoms in the interfacial layer, so that the interfacial layer may be scavenged in subsequent thermal processes. Such would result in an increase in the trap density of the interfacial layer, which may adversely affect the quality of the interfacial layer.

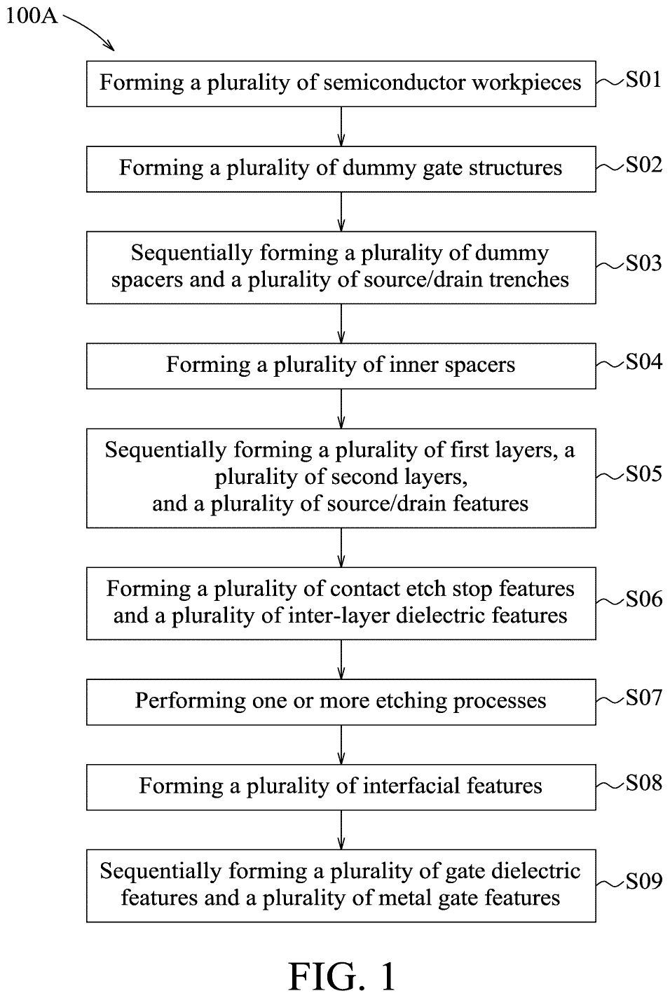

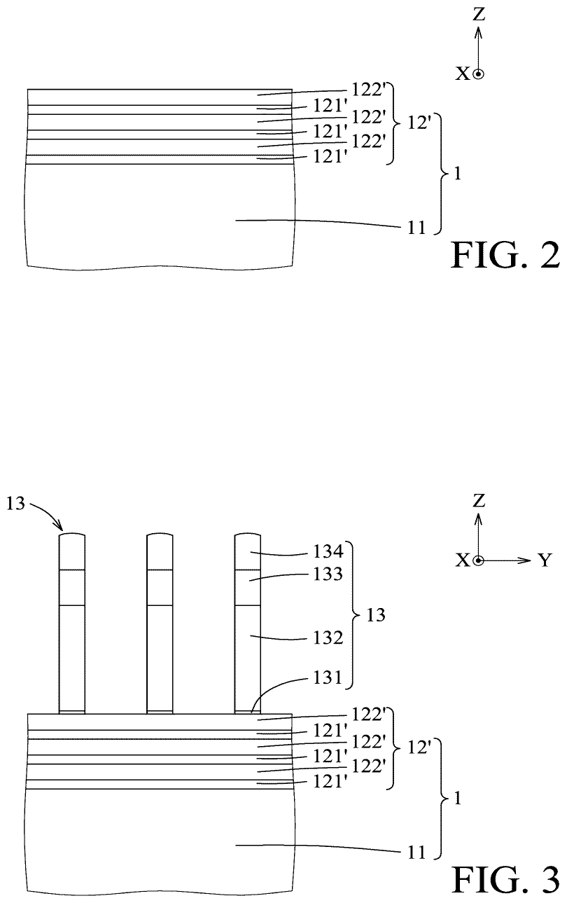

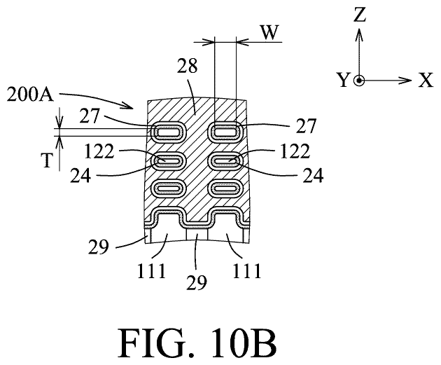

The present disclosure is directed to a semiconductor device and a method for manufacturing the same. FIG. 1 is a flow diagram illustrating a method 100A for manufacturing a semiconductor device 200A shown in FIGS. 10A and 10B in accordance with some embodiments. FIGS. 2 to 9E illustrate schematic views of some intermediate stages of the method 100A. Some portions may be omitted in FIGS. 2 to 9E for the sake of brevity. Additional steps can be provided before, after or during the method 100A, and some of the steps described herein may be replaced by other steps or be eliminated.

Referring to FIG. 1 and the example illustrated in FIG. 2, the method 100A begins at step S01, where a plurality of semiconductor workpieces 1 are formed. One of the semiconductor workpieces 1 is shown in FIG. 2. Step S01 may include sub-step (i) of forming a nanosheet stack (not shown) over a semiconductor substrate 11, and sub-step (ii) of etching portions of the nanosheet stack so as to form the semiconductor workpieces 1. In some embodiments, the semiconductor substrate 11 may include, for example, but not limited to, an elemental semiconductor or a compound semiconductor. The elemental semiconductor includes a single species of atoms, such as silicon or germanium from column XIV of the periodic table, and may be crystalline, polycrystalline, or amorphous in structure. Other suitable materials for the elemental semiconductor are within the contemplated scope of the present disclosure. The compound semiconductor includes two or more elements, and examples thereof may include, silicon carbide, gallium arsenide, gallium phosphide, indium phosphide, indium arsenide, indium antimonide, silicon germanium, gallium arsenide phosphide, aluminum indium arsenide, aluminum gallium arsenide, gallium indium arsenide, gallium indium phosphide, and gallium indium arsenide phosphide. Other suitable materials for the compound semiconductor are within the contemplated scope of the present disclosure. The compound semiconductor may have a gradient feature in which the compositional ratio thereof changes from one location to another location in the compound semiconductor. The compound semiconductor may be formed over a silicon substrate and may be strained. In some embodiments, the semiconductor substrate 11 may include a multilayer compound semiconductor structure. In some embodiments, the nanosheet stack includes a plurality of sacrificial layers (not shown) and a plurality of channel layers (not shown) which are alternately stacked on the semiconductor substrate 11. In some embodiments, the sacrificial layers may include silicon germanium. Other suitable materials for the sacrificial layers are within the contemplated scope of the present disclosure. In some embodiments, the channel layers may include silicon. Other suitable materials for the channel layers are within the contemplated scope of the present disclosure. The sacrificial layers and the channel layers may be formed by a suitable deposition process, for example, but not limited to, chemical vapor deposition (CVD) (e.g., ultra-high vacuum CVD (UHV-CVD)) or other suitable deposition processes. In some embodiments, the sacrificial layers and the channel layers may be formed by a suitable epitaxial growth process, for example, but not limited to, molecular beam epitaxy (MBE) or other suitable epitaxial growth processes. In some embodiments, the semiconductor workpieces 1 are spaced apart from one another in an X direction, which is parallel to an upper surface of the semiconductor substrate 11. In some embodiments, each of the semiconductor workpieces 1 includes a portion of the semiconductor substrate 11 and a semiconductor stack 12′ disposed on the portion of the semiconductor substrate 11 in a Z direction transverse to the X direction. In some embodiments, the semiconductor stack 12′ includes a plurality of sacrificial layer portions 121′ which are respective parts of the sacrificial layers of the nanosheet stack, and a plurality of channel layer portions 122′ which are respective parts of the channel layers of the nanosheet stack, where the sacrificial layer portions 121′ and the channel layer portions 122′ are alternately stacked over one another along the Z direction.

Referring to FIG. 1 and the example illustrated in FIG. 3, the method 100A then proceeds to step S02, where a plurality of dummy gate structures 13 are formed on the semiconductor workpieces 1 in the Z direction. The dummy gate structures 13 are spaced apart from one another in a Y direction transverse to the X direction and the Z direction. Each of the dummy gate structures 13 includes a dummy gate dielectric 131, a dummy gate 132, a mask layer 133, and a mask layer 134 that are sequentially formed on the semiconductor workpieces 1 in the Z direction. Step S02 may include sub-step (i) of sequentially depositing respective material layers for the dummy gate dielectric 131, the dummy gate 132, the mask layer 133, and the mask layer 134 on the semiconductor workpieces 1, and sub-step (ii) of patterning the material layers by a photolithography process, so as to obtain the dummy gate dielectric 131, the dummy gate 132, the mask layer 133, and the mask layer 134. In some embodiments, sub-step (i) may be conducted by a suitable deposition process, for example, but not limited to, CVD, atomic layer deposition (ALD), physical vapor deposition (PVD), plasma-enhanced CVD (PECVD), plasma-enhanced ALD (PEALD), or other suitable deposition processes. Other suitable processes are within the contemplated scope of the present disclosure.

The dummy gate dielectric 131 is disposed on the semiconductor workpieces 1 and may include silicon oxide. Other suitable materials for forming the dummy gate dielectric 131 are within the contemplated scope of the present disclosure. In some embodiments, the dummy gate dielectric 131 may serve as an etch stop layer.

The dummy gate 132 is disposed on the dummy gate dielectric 131 opposite to the semiconductor workpieces 1. In some embodiments, the dummy gate 132 may include polysilicon. Other suitable materials for forming the dummy gate 132 are within the contemplated scope of the present disclosure.

The mask layer 133 is disposed on the dummy gate 132 opposite to the dummy gate dielectric 131, and may be made of a nitride-based material (e.g., silicon nitride). The mask layer 134 is disposed on the mask layer 133 opposite to the dummy gate 132, and may be made of an oxide-based material (e.g., silicon oxide). Other suitable materials for forming the mask layer 133 and the mask layer 134 are within the contemplated scope of the present disclosure.

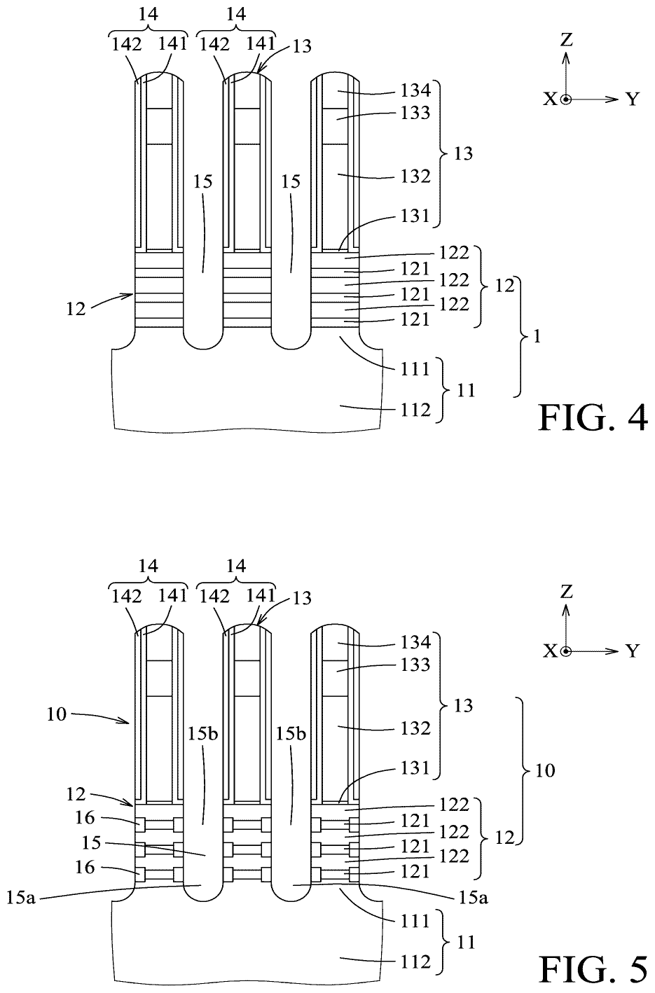

Referring to FIG. 1 and the example illustrated in FIG. 4, the method 100A then proceeds to step S03, where a plurality of dummy spacers 14 are formed to laterally cover the dummy gate structures 13, followed by recessing the semiconductor stack 12′ (see FIG. 3) to form a plurality of source/drain trenches 15. Step S03 may include sub-step (i) of conformally forming at least one dummy spacer material layer (not shown) over the structure shown in FIG. 3, sub-step (ii) of anisotropically etching the at least one dummy spacer material layer such that horizontal portions of the at least one dummy spacer material layer are etched away to form the dummy spacers 14, and then sub-step (iii) of conducting a photolithography process to recess the semiconductor stack 12′, thereby forming the source/drain trenches 15 and a plurality of stacked structures 12, two adjacent ones of which are spaced apart from each other by a corresponding one of the source/drain trenches 15. Each of the stacked structures 12 includes a plurality of sacrificial features 121 and a plurality of channel features 122 disposed to alternate with the sacrificial features 121 in the Z direction.

In some embodiments, the at least one dummy spacer material layer for forming the dummy spacers 14 may include, for example, but not limited to, silicon oxide, silicon nitride, silicon carbide, silicon oxycarbide, silicon oxynitride, silicon carbonitride, silicon oxycarbonitride, or combinations thereof. Other suitable materials for forming the dummy spacers 14 are within the contemplated scope of the present disclosure. In some embodiments, the at least one dummy spacer material layer may be formed by a suitable deposition process, for example, but not limited to, CVD, PECVD, PVD, ALD, PEALD, or other suitable deposition processes. Other suitable processes for forming the dummy spacers 14 are within the contemplated scope of the present disclosure. In some embodiments, each of the dummy spacers 14 may include an inner dummy spacer 141 that laterally covers a corresponding one of the dummy gate structures 13, and an outer dummy spacer 142 that is disposed on a sidewall of the inner dummy spacer 141. The source/drain trenches 15 are spaced apart from each other in the Y direction. Each of the source/drain trenches 15 may penetrate an upper portion 111 of the semiconductor substrate 11, and may terminate at a lower portion 112 of the semiconductor substrate 11.

Referring to FIG. 1 and the example illustrated in FIG. 5, the method 100A then proceeds to step S04, where a plurality of inner spacers 16 are formed. Step S04 may include: sub-step (i) of laterally recessing the sacrificial features 121 by an isotropic etching process to remove side portions of the sacrificial features 121 based on a relatively high etching selectivity of the sacrificial features 121 with respect to the channel features 122, so as to form lateral recesses (not shown); sub-step (ii) of conformally forming an inner spacer material layer (not shown) to cover the semiconductor substrate 11, the channel features 122, the dummy gate structures 13 and the dummy spacers 14, and to fill the lateral recesses; and sub-step (iii) of isotropically etching the inner spacer material layer to form the inner spacers 16 in the lateral recesses so as to laterally cover the sacrificial features 121. After this step, a plurality of fin structures 10 are formed accordingly. The fin structures 10 are disposed on the semiconductor substrate 11 and are spaced apart from each other in the Y direction. Each of the fin structures 10 includes a corresponding one of the stacked structures 12 disposed on the semiconductor substrate 11, a corresponding one of the dummy gate structures 13 disposed on the corresponding one of the stacked structures 12 in the Z direction, and the inner spacers 16 laterally covering the sacrificial features 121.

In some embodiments, the isotropic etching process for laterally recessing the sacrificial features 121 may be a dry isotropic etching process, a wet isotropic etching process, or a combination thereof. In some embodiments, the inner spacer material layer for forming the inner spacers 16 may include, for example, but not limited to, silicon oxide, silicon nitride, silicon carbide, silicon oxycarbide, silicon oxynitride, silicon carbonitride, silicon oxycarbonitride, low-dielectric constant (k) materials, or combinations thereof. Other suitable materials for forming the inner spacers 16 are within the contemplated scope of the present disclosure. In some embodiments, the inner spacer material layer may be formed by a suitable deposition process, for example, but not limited to, CVD, PECVD, PVD, ALD, PEALD, or other suitable deposition processes. Other suitable processes for forming the inner spacers 16 are within the contemplated scope of the present disclosure.

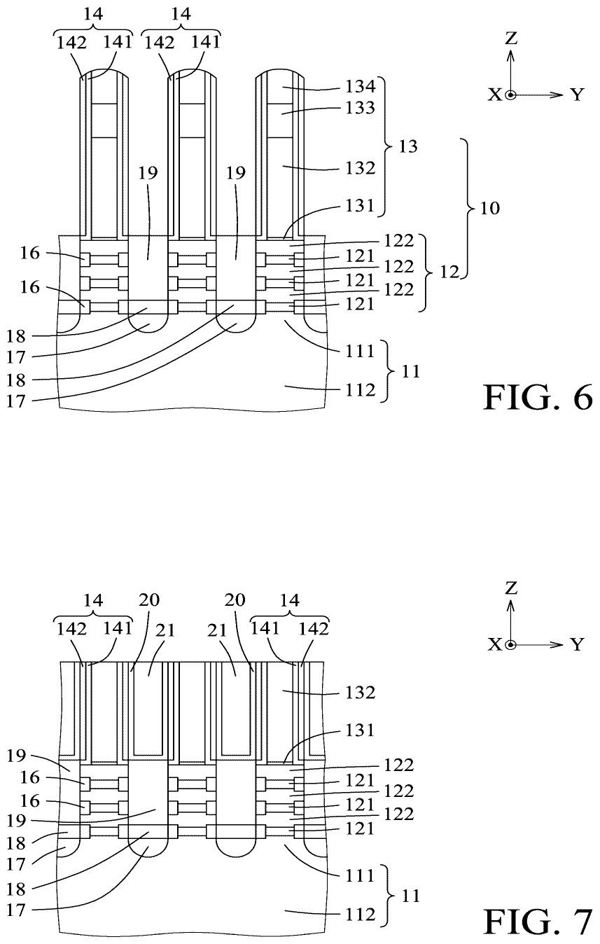

Referring to FIG. 1 and the example illustrated in FIG. 6, the method 100A then proceeds to step S05, where a plurality of first layers 17, a plurality of second layers 18, and a plurality of source/drain features 19 are sequentially formed. Step S05 may include sub-steps (i) to (iii).

In sub-step (i), the first layers 17 are respectively formed in lower trench portions 15a of the source/drain trenches 15 (see FIG. 5). In some embodiments, the first layers 17 may be made of a semiconductor material, for example, but not limited to, silicon. Other suitable materials for forming the first layers 17 are within the contemplated scope of the present disclosure. In some embodiments, the first layers 17 may be formed by, for example, but not limited to, a deposition process (e.g., CVD), an epitaxial growth process (e.g., MBE), an epitaxial deposition/partial etch process (e.g., cyclic deposition-etch (CDE) process), or a selective epitaxial growth (SEG) process. Other suitable processes for forming the first layers 17 are within the contemplated scope of the present disclosure.

In sub-step (ii), the second layers 18 are respectively formed on the first layers 17 in the source/drain trenches 15. In some embodiments, the second layers 18 may be made of a dielectric material, for example, but not limited to, silicon oxide or silicon nitride. Other suitable materials for forming the second layers 18 are within the contemplated scope of the present disclosure. In some embodiments, the second layers 18 may be formed by a suitable deposition process, for example, but not limited to, CVD, ALD, or other suitable deposition processes. Other suitable processes for forming the second layers 18 are within the contemplated scope of the present disclosure.

In sub-step (iii), the source/drain features 19 are respectively formed on the second layers 18 in upper trench portions 15b of the source/drain trenches 15 (see FIG. 5). In some embodiments, the source/drain features 19 may be made of silicon phosphide, silicon germanium, or silicon germanium boron. Other suitable materials for forming the source/drain features 19 are within the contemplated scope of the present disclosure. In some embodiments, the source/drain features 19 may be formed by a suitable epitaxial growth process (e.g., MBE). Other suitable processes for forming the source/drain features 19 are within the contemplated scope of the present disclosure. In some embodiments, the first layers 17, the second layers 18, and the source/drain features 19 together serve as source/drain regions.

Referring to FIG. 1 and the example illustrated in FIG. 7, the method 100A then proceeds to step S06, where a plurality of contact etch stop features 20 and a plurality of inter-layer dielectric (ILD) features 21 are respectively formed on the source/drain features 19. Step S06 may include sub-steps (i) to (iii).

In sub-step (i), a contact etch stop layer (not shown) for forming the contact etch stop features 20 is formed on the structure shown in FIG. 6 by a blanket deposition process, for example, but not limited to, CVD or molecular layer deposition (MLD). Other suitable processes for forming the contact etch stop layer are within the contemplated scope of the present disclosure. In some embodiments, the contact etch stop layer may include, for example, but not limited to, silicon nitride, carbon-doped silicon nitride, or a combination thereof. Other suitable materials for forming the contact etch stop layer are within the contemplated scope of the present disclosure.

In sub-step (ii), a dielectric material layer (not shown) for forming the ILD features 21 are sequentially formed on the structure obtained after sub-step (i) by a blanket deposition process, for example, but not limited to, CVD or MLD. Other suitable processes for forming the dielectric material layer are within the contemplated scope of the present disclosure. In some embodiments, the dielectric material layer may include, for example, but not limited to, silicon oxide, silicon nitride, silicon oxynitride, or combinations thereof. Other suitable materials for forming the dielectric material layer are within the contemplated scope of the present disclosure.

In sub-step (iii), a planarization process is performed to remove an excess portion of the contact etch stop layer, an excess portion of the dielectric material layer, the mask layer 133, the mask layer 134, and portions of the dummy spacers 14, so as to obtain the contact etch stop features 20 and the ILD features 21. In some embodiments, the planarization process may be, for example, but not limited to, chemical mechanical polishing (CMP). Other suitable planarization processes are within the contemplated scope of the present disclosure.

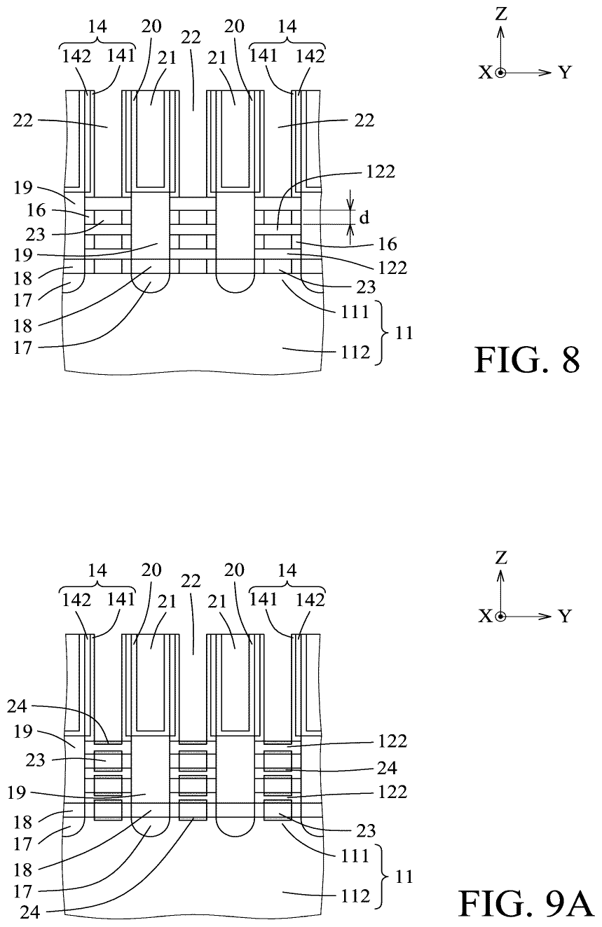

Referring to FIG. 1 and the example illustrated in FIG. 8, the method 100A then proceeds to step S07, where the sacrificial features 121, the dummy gate dielectrics 131, and the dummy gates 132 (see FIG. 7) are removed, so as to form a plurality of first voids 22 and a plurality of second voids 23. Step S07 may be performed by one or more etching processes. The etching processes may include a wet etching process, a dry etching process, or a combination thereof. Other suitable etching processes are within the contemplated scope of the present disclosure. The first voids 22 are defined by the inner dummy spacers 141 and an uppermost one of the channel features 122, and the second voids 23 are defined by the inner spacers 16 and the channel features 122. In some embodiments, two adjacent ones of the channel features 122 may be separated by a distance (d) ranging from about 8 Å to about 12 Å.

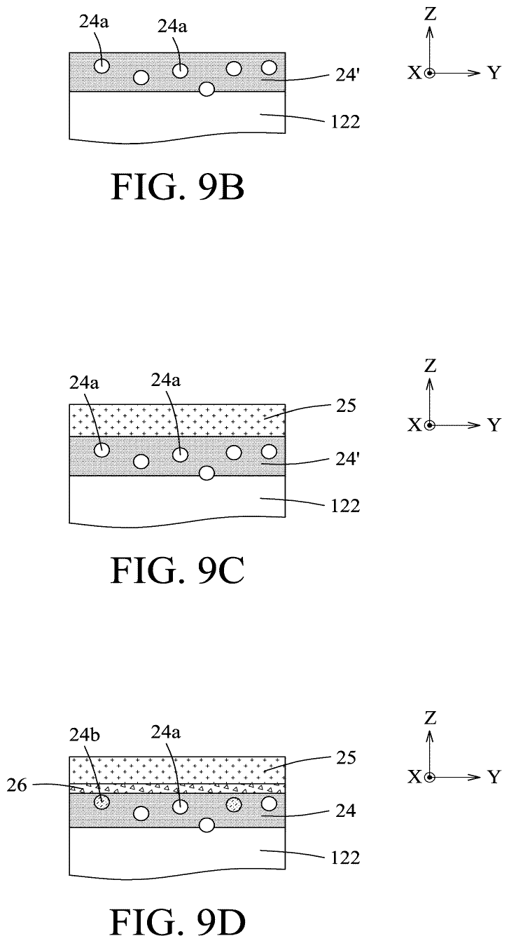

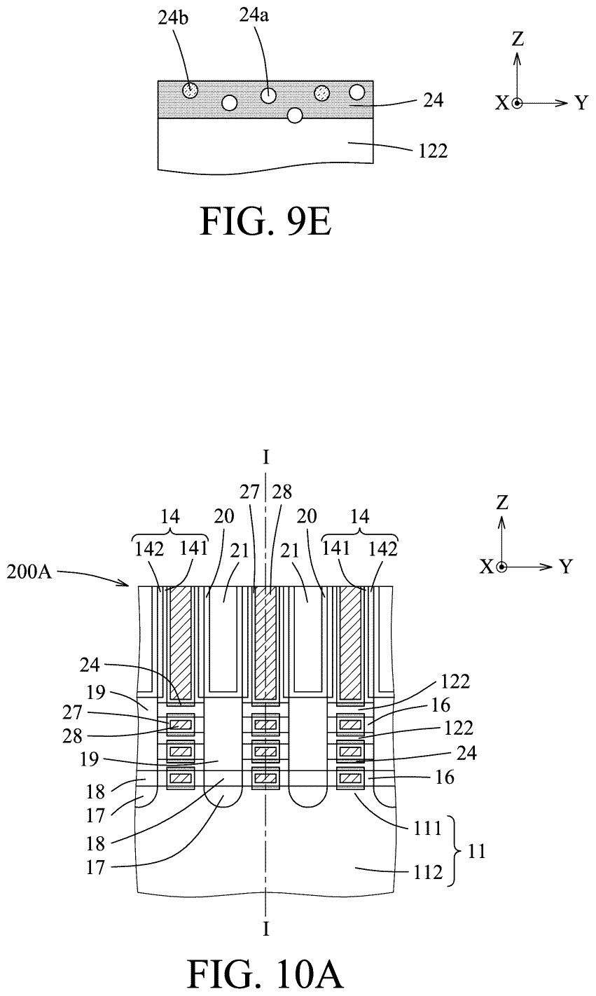

Referring to FIG. 1 and the example illustrated in FIGS. 9A to 9E, the method 100A then proceeds to step S08, where a plurality of interfacial features 24 are formed. Step S08 includes sub-steps (i) to (iv).

In sub-step (i), as shown in FIG. 9B, an interfacial material layer 24′ is formed by subjecting the channel features 122 and the upper portion 111 of the semiconductor substrate 11 to surface oxidation. FIG. 9B only shows that the interfacial material layer 24′ is formed by the surface oxidation of the channel features 122. The interfacial material layer 24′ covers each of the channel features 122. In some embodiments, the interfacial material layer 24′ may include, for example, but not limited to, silicon dioxide (SiO₂, i.e., stoichiometric silicon oxide). In some embodiments, the interfacial material layer 24′ may be formed by soaking the structure shown in FIG. 8 in a heated chemical agent so as to obtain the interfacial material layer 24′ with a saturation thickness. In some embodiments, the chemical agent may include, for example, but not limited to, carbonated deionized water (DICO₂), deionized water, ozonated deionized water, an ammonia aqueous solution, hydrochloric acid, sulfuric acid, hydrogen peroxide, or combinations thereof. Other suitable chemical agents are within the contemplated scope of the present disclosure. In some embodiments, the structure shown in FIG. 8 may be soaked in the heated chemical agent at a temperature ranging from about 50° C. to about 75° C. If the temperature is lower than about 50° C., the saturation thickness of the interfacial material layer 24′ is difficult to be reached. If the temperature is greater than about 75° C., a composition ratio of the chemical agent may be changed and the saturation thickness of the interfacial material layer 24′ is difficult to be reached. In some embodiments, the structure shown in FIG. 8 may be soaked in the heated chemical agent at a time period ranging from about 60 seconds to about 200 seconds. If the time period is less than about 60 seconds, the saturation thickness of the interfacial material layer 24′ is difficult to be reached. In some embodiments, the saturation thickness of the interfacial material layer 24′ may range from about 8 Å to about 15 Å.

In sub-step (ii), as shown in FIG. 9C, a metal oxide layer 25 is conformally formed on the structure obtained after sub-step (i). In some embodiments, the metal oxide layer 25 may include, for example, but not limited to, yttrium oxide, scandium oxide, lutetium oxide, lanthanum oxide, zinc oxide, or combinations thereof. Other suitable metal oxide materials are within the contemplated scope of the present disclosure. In some embodiments, the metal oxide layer 25 may be conformally formed by a suitable deposition process, for example, but not limited to, CVD or ALD. In this case, the metal oxide layer 25 can be conformally formed by CVD or ALD on any geometrical structure (i.e., without a structure loading effect). Other suitable processes for forming the metal oxide layer 25 are within the contemplated scope of the present disclosure. In some embodiments, the metal oxide layer 25 may have a thickness ranging from about 3 Å to about 15 Å. If the thickness of the metal oxide layer 25 is less than about 3 Å, the metal oxide layer 25 may have a poor coverage on the structure obtained after sub-step (i). If the thickness of the metal oxide layer 25 is greater than about 15 A, the metal oxide layer 25 may not be easily removed (which will be described in sub-step (iv)). In some embodiments, the metal oxide layer 25 may have a carbon concentration that is lower than about 1%. If the carbon concentration in the metal oxide layer 25 is greater than about 1%, reliability of the semiconductor device 200A formed accordingly may be adversely affected. In some embodiments, the metal oxide layer 25 may provide oxygen atoms to compensate oxygen vacancies 24a of the interfacial material layer 24′.

In sub-step (iii), as shown in FIG. 9D, a metal silicate layer 26 and the interfacial features 24 are formed, in which the metal silicate layer 26 is formed between each of the interfacial features 24 and the metal oxide layer 25. The metal silicate layer 26 is formed by consuming silicon atoms from the interfacial material layer 24′, and includes metal atoms derived from the metal oxide layer 25. In some embodiments, the metal silicate layer 26 may be spontaneously formed due to consumption of silicon atoms on a surface of the interfacial material layer 24′ (silicon atoms may be attracted to and captured by the metal oxide layer 25). In some embodiments, a thermal treatment may be performed on the structure obtained after sub-step (ii) to facilitate formation of the metal silicate layer 26. In some embodiments, the thermal treatment may be an annealing treatment. In some embodiments, the annealing treatment may be performed at a temperature ranging from about 500° C. to about 800° C. If the temperature of the annealing treatment is lower than about 500° C., uniformity of the metal silicate layer 26 may be adversely affected. If the temperature of the annealing treatment is higher than about 800° C., metal atoms of the metal oxide layer 25 may diffuse into the channel features 122. In some embodiments, the time period for performing the annealing treatment may range from about 10 seconds to about 60 seconds. Similarly, if the time period of the annealing treatment is less than about 10 seconds, the uniformity of the metal silicate layer 26 may be adversely affected. If the time period of the annealing treatment is greater than about 60 seconds, the metal atoms of the metal oxide layer 25 may diffuse into the channel features 122. In some embodiments, the metal silicate layer 26 may have a thickness ranging from about 3 Å to about 5 Å. In some embodiments, after this sub-step, the thickness of the interfacial material layer 24′ is reduced due to the formation of the metal silicate layer 26, and some of the oxygen vacancies 24a of the interfacial material layer 24′ may be occupied by oxygen atoms 24b derived from the metal oxide layer 25.

In sub-step (iv), as shown in FIG. 9E, the metal oxide layer 25 and the metal silicate layer 26 are removed by a wet treatment so as to form the structure shown in FIG. 9A. In some embodiments, the wet treatment is performed using a wet chemical agent, for example, but not limited to, hot deionized water (HDI), a mixture of hydrochloric acid, hydrogen peroxide and deionized water (a ratio thereof in the mixture ranging from about 1:1:2 to about 1:1:10), dilute hydrochloric acid (dHCl, a mixture of hydrochloric acid and deionized water and a ratio thereof in the mixture ranging from about 1:20 to about 1:100), or carbonated deionized water (DICO₂). Other suitable wet chemical agents used in the wet treatment are within the contemplated scope of the present disclosure. In some embodiments, after this sub-step, in comparison to the thickness of the interfacial material layer 24′, the thicknesses of the interfacial features 24 thus formed are reduced because a portion of the interfacial material layer 24′ is converted into the metal silicate layer 26, which is then removed. It is noted that removal of the metal silicate layer 26 may depend on the temperature and the time period of the wet treatment. In addition, a slight increase in the time period of the wet treatment may not affect quality of the interfacial features 24 thus formed.

After step S08, the interfacial material layer 24′ is formed into the interfacial features 24. Each of the interfacial features 24 has a thickness less than the thickness of the interfacial material layer 24′. In some embodiments, the thickness of each of the interfacial features 24 ranges from about 5 Å to about 12 Å. In some embodiments, a thickness difference between the interfacial material layer 24′ and each of the interfacial features 24 ranges from about 4 Å to about 10 Å. The interfacial features 24 thus formed include silicon oxide (SiO₂) in a stoichiometric state (i.e., SiO₂ with a ratio of silicon to oxygen atom being 1:2), and have a high thermal stability, and are formed with good robustness in which each silicon atom is covalently bonded to four oxygen atoms in a tetrahedral manner. In addition, each of the interfacial features 24 may have hydroxyl (—OH) bonds on a surface thereof due to the use of hydrogen peroxide in the wet treatment (i.e., sub-step (iv)), which is conducive to improving uniformity of gate dielectric features 27 that are subsequently formed on the interfacial features 24 (i.e., step S09).

By having the interfacial features 24 with a reduced thickness, a good robustness and a high thermal stability, the EOT of the semiconductor device 200A can be reduced, the uniformity of the gate dielectric features 27 can be improved, and gate leakage of the semiconductor device 200A can be reduced.

Referring to FIG. 1 and the example illustrated in FIGS. 10A and 10B, the method 100A then proceeds to step S09, where the gate dielectric features 27 and a plurality of metal gate features 28 are sequentially formed in the first voids 22 and the second voids 23 (see FIG. 9A). FIG. 10B illustrates a cross-sectional view taken along line I-I of FIG. 10A. Step S09 may include sub-steps (i) and (ii).

In sub-step (i), a dielectric material film (not shown) for forming the gate dielectric features 27 and a conductive material film (not shown) for forming the metal gate features 28 are sequentially formed in the first voids 22 and the second voids 23, and over the dummy spacers 14, the contact etch stop features 20 and the ILD features 21. In some embodiments, the dielectric material film may be made of a high-k material. In some embodiments, the high-k material may be a wide bandgap insulator material with a good thermal stability. In some embodiments, the high-k material may be magnesium oxide, calcium oxide, aluminum oxide, zirconium silicate, scandium oxide, or combinations thereof. Other suitable high-k materials for forming the dielectric material film are within the contemplated scope of the present disclosure. In some embodiments, the dielectric material film may be formed by a suitable deposition process, for example, but not limited to, CVD or ALD. Other suitable processes for forming the dielectric material film are within the contemplated scope of the present disclosure. In some embodiments, the conductive material film may include, for example, but not limited to, aluminum, copper, tungsten, cobalt, ruthenium, titanium, tantalum, molybdenum, nickel, platinum, or combinations thereof. In some embodiments, the conductive material film may be made of an N-type metal, a P-type metal, or a combination thereof. Other suitable materials for forming the conductive material film are within the contemplated scope of the present disclosure. In some embodiments, the conductive material film may be formed by a suitable deposition process, for example, but not limited to, CVD, PVD, or electroless plating. Other suitable processes for forming the conductive material film are within the contemplated scope of the present disclosure.

In sub-step (ii), a planarization process (e.g., CMP or other suitable planarization processes) is performed to remove an excess portion of the dielectric material film and an excess portion of the conductive material film over the dummy spacers 14, the contact etch stop features 20 and the ILD features 21, so as to obtain the gate dielectric features 27 and the metal gate features 28.

After step S09, the semiconductor device 200A is obtained. In some embodiments, the semiconductor device 200A may be a nanosheet field-effect transistor. In some embodiments, each of the interfacial features 24 is surrounded and covered by a corresponding one of the gate dielectric features 27. In some embodiments, as shown in FIG. 10B, each of the channel features 122 may have a thickness (T) ranging from about 5 nm to about 8 nm. In some embodiments, each of the channel features 122 may have a width (W) ranging from about 15 nm to about 50 nm. In some embodiments, each of the upper portions 111 of the semiconductor substrate 11 is located between corresponding two adjacent ones of isolation portions 29. In some embodiments, each of the isolation portions 29 may be a portion of a shallow trench isolation (STI), a deep trench isolation (DTI), or other suitable isolation structures.

In a semiconductor device of this disclosure, each of a plurality of interfacial features may have a smaller size (e.g., being relatively thin) and an improved quality (e.g., less defects and high thermal stability), which are conducive to improving quality of a plurality of gate dielectric features that are subsequently formed on the interfacial features, reducing the EOT of the semiconductor device, and reducing gate leakage current of the semiconductor device, without reducing thicknesses of the gate dielectric features. In addition, the thickness of each of the interfacial features will not undesirably increase after a gate loop thermal process for forming the gate dielectric features and a plurality of metal gate features. Formation of the interfacial features involves sequentially depositing an interfacial material layer and a metal oxide layer on a plurality of silicon channel features to form a metal silicate layer on the silicon channel features, followed by removing the metal oxide layer and the metal silicate layer.

In accordance with some embodiments of the present disclosure, a method for manufacturing a semiconductor device includes: forming a semiconductor structure on a semiconductor substrate, the semiconductor structure including a first source/drain region and a second source/drain region which are disposed on the semiconductor substrate in a first direction normal to the semiconductor substrate and which are spaced apart from each other in a second direction transverse to the first direction, and a plurality of channel features which are disposed between and connected to the first source/drain region and the second source/drain region and which are spaced apart from one another in the first direction; forming an interfacial material layer to cover the plurality of channel features; forming a metal oxide layer on the interfacial material layer; converting a portion of the interfacial material layer into a metal silicate layer so as to form a plurality of interfacial features respectively covering the plurality of channel features, the metal silicate layer being formed between the metal oxide layer and each of the plurality of interfacial features; and removing the metal oxide layer and the metal silicate layer.

In accordance with some embodiments of the present disclosure, the interfacial material layer includes silicon dioxide.

In accordance with some embodiments of the present disclosure, the metal oxide layer includes yttrium oxide, scandium oxide, lutetium oxide, lanthanum oxide, zinc oxide, or combinations thereof.

In accordance with some embodiments of the present disclosure, the metal oxide layer is formed by atomic layer deposition or chemical vapor deposition.

In accordance with some embodiments of the present disclosure, the metal oxide layer has a thickness ranging from about 3 Å to about 15 Å.

In accordance with some embodiments of the present disclosure, the metal oxide layer has a carbon concentration that is lower than about 1%.

In accordance with some embodiments of the present disclosure, the metal silicate layer has a thickness ranging from about 3 Å to about 5 Å.

In accordance with some embodiments of the present disclosure, the interfacial material layer has a thickness ranging from about 8 Å to about 15 Å.

In accordance with some embodiments of the present disclosure, each of the interfacial features has a thickness ranging from about 5 Å to about 12 Å.

In accordance with some embodiments of the present disclosure, a method for manufacturing a semiconductor device includes: forming a semiconductor structure on a semiconductor substrate, the semiconductor structure including a first source/drain region and a second source/drain region which are disposed on the semiconductor substrate in a first direction normal to the semiconductor substrate and which are spaced apart from each other in a second direction transverse to the first direction, and a plurality of channel features which are disposed between and connected to the first source/drain region and the second source/drain region and which are spaced apart from one another in the first direction; subjecting the plurality of channel features to surface oxidation so as to form an interfacial material layer to cover each of the plurality of channel features; forming a metal oxide layer on the interfacial material layer; converting a portion of the interfacial material layer into a metal silicate layer so as to form a plurality of interfacial features respectively covering the plurality of channel features, the metal silicate layer being formed between the metal oxide layer and each of the plurality of interfacial features; and removing the metal oxide layer and the metal silicate layer.

In accordance with some embodiments of the present disclosure, the surface oxidation is performed by soaking the semiconductor structure in a heated chemical agent that includes carbonated deionized water, deionized water, ozonated deionized water, an ammonia aqueous solution, hydrochloric acid, sulfuric acid, hydrogen peroxide, or combinations thereof.

In accordance with some embodiments of the present disclosure, the surface oxidation is performed at a temperature ranging from about 50° C. to about 75° C.

In accordance with some embodiments of the present disclosure, the surface oxidation is performed for a time period ranging from about 60 seconds to about 200 seconds.

In accordance with some embodiments of the present disclosure, the metal oxide layer and the metal silicate layer are removed by soaking the semiconductor structure in a chemical agent that includes hot deionized water, a mixture of hydrochloric acid, hydrogen peroxide and deionized water, dilute hydrochloric acid, or carbonated deionized water.

In accordance with some embodiments of the present disclosure, a method for manufacturing a semiconductor device includes: forming a semiconductor structure on a semiconductor substrate, the semiconductor structure including a first source/drain region and a second source/drain region which are disposed on the semiconductor substrate in a first direction normal to the semiconductor substrate and which are spaced apart from each other in a second direction transverse to the first direction, and a plurality of channel features which are disposed between and connected to the first source/drain region and the second source/drain region and which are spaced apart from one another in the first direction; forming an interfacial material layer to cover each of the plurality of channel features; forming a metal oxide layer on the interfacial material layer; subjecting the interfacial material layer and the metal oxide layer to thermal treatment, so as to form a metal silicate layer and a plurality of interfacial features respectively covering the plurality of channel features, the metal silicate layer being formed between the metal oxide layer and each of the plurality of interfacial features; and removing the metal oxide layer and the metal silicate layer.

In accordance with some embodiments of the present disclosure, the surface oxidation is performed by soaking the semiconductor structure in a heated chemical agent that includes carbonated deionized water, deionized water, ozonated deionized water, an ammonia aqueous solution, hydrochloric acid, sulfuric acid, hydrogen peroxide, or combinations thereof.

In accordance with some embodiments of the present disclosure, the surface oxidation is performed at a temperature ranging from about 50° C. to about 75° C.

In accordance with some embodiments of the present disclosure, the surface oxidation is performed for a time period ranging from about 60 seconds to about 200 seconds.

In accordance with some embodiments of the present disclosure, the metal oxide layer and the metal silicate layer are removed by soaking the semiconductor structure in a chemical agent that includes hot deionized water, a mixture of hydrochloric acid, hydrogen peroxide and deionized water, dilute hydrochloric acid, or carbonated deionized water.

In accordance with some embodiments of the present disclosure, a method for manufacturing a semiconductor device includes: forming a semiconductor structure on a semiconductor substrate, the semiconductor structure including a first source/drain region and a second source/drain region which are disposed on the semiconductor substrate in a first direction normal to the semiconductor substrate and which are spaced apart from each other in a second direction transverse to the first direction, and a plurality of channel features which are disposed between and connected to the first source/drain region and the second source/drain region and which are spaced apart from one another in the first direction; forming an interfacial material layer to cover each of the plurality of channel features; forming a metal oxide layer on the interfacial material layer; subjecting the interfacial material layer and the metal oxide layer to thermal treatment, so as to form a metal silicate layer and a plurality of interfacial features respectively covering the plurality of channel features, the metal silicate layer being formed between the metal oxide layer and each of the plurality of interfacial features; and removing the metal oxide layer and the metal silicate layer.

In accordance with some embodiments of the present disclosure, the thermal treatment is performed at a temperature ranging from about 500° C. to about 800° C.

In accordance with some embodiments of the present disclosure, the thermal treatment is performed for a time period ranging from about 10 seconds to about 600 seconds.

In accordance with some embodiments of the present disclosure, the thermal treatment is an annealing treatment.

In accordance with some embodiments of the present disclosure, a thickness difference between the interfacial material layer and each of the interfacial features ranges from about 4 Å to about 10 Å.

In accordance with some embodiments of the present disclosure, the method for manufacturing the semiconductor device further includes: after removal of the metal oxide layer and the metal silicate layer, forming a plurality of gate dielectric features, each of which covers the interfacial features and includes magnesium oxide, calcium oxide, aluminum oxide, zirconium silicate, scandium oxide, or combinations thereof.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor device, comprising:
forming a semiconductor structure on a semiconductor substrate, the semiconductor structure including
a first source/drain region and a second source/drain region which are disposed on the semiconductor substrate in a first direction normal to the semiconductor substrate and which are spaced apart from each other in a second direction transverse to the first direction, and
a plurality of channel features which are disposed between and connected to the first source/drain region and the second source/drain region and which are spaced apart from one another in the first direction;
forming an interfacial material layer to cover each of the plurality of channel features;
forming a metal oxide layer on the interfacial material layer;
converting a portion of the interfacial material layer into a metal silicate layer so as to form a plurality of interfacial features respectively covering the plurality of channel features, the metal silicate layer being formed between the metal oxide layer and each of the plurality of interfacial features; and
removing the metal oxide layer and the metal silicate layer.

2. The method as claimed in claim 1, wherein the interfacial material layer includes silicon dioxide.

3. The method as claimed in claim 1, wherein the metal oxide layer includes yttrium oxide, scandium oxide, lutetium oxide, lanthanum oxide, zinc oxide, or combinations thereof.

4. The method as claimed in claim 1, wherein the metal oxide layer is formed by atomic layer deposition or chemical vapor deposition.

5. The method as claimed in claim 1, wherein the metal oxide layer has a thickness ranging from 3 Å to 15 Å.

6. The method as claimed in claim 1, wherein the metal oxide layer has a carbon concentration that is lower than 1%.

7. The method as claimed in claim 1, wherein the metal silicate layer has a thickness ranging from 3 Å to 5 Å.

8. The method as claimed in claim 1, wherein the interfacial material layer has a thickness ranging from 8 Å to 15 Å.

9. The method as claimed in claim 8, wherein each of the interfacial features has a thickness ranging from 5 Å to 12 Å.

10. A method for manufacturing a semiconductor device, comprising:
forming a semiconductor structure on a semiconductor substrate, the semiconductor structure including
a first source/drain region and a second source/drain region which are disposed on the semiconductor substrate in a first direction normal to the semiconductor substrate and which are spaced apart from each other in a second direction transverse to the first direction, and
a plurality of channel features which are disposed between and connected to the first source/drain region and the second source/drain region and which are spaced apart from one another in the first direction;
subjecting the plurality of channel features to surface oxidation so as to form an interfacial material layer to cover each of the plurality of channel features;
forming a metal oxide layer on the interfacial material layer;
converting a portion of the interfacial material layer into a metal silicate layer so as to form a plurality of interfacial features respectively covering the plurality of channel features, the metal silicate layer being formed between the metal oxide layer and each of the plurality of interfacial features; and
removing the metal oxide layer and the metal silicate layer.

11. The method as claimed in claim 10, wherein the surface oxidation is performed by soaking the semiconductor structure in a heated chemical agent that includes carbonated deionized water, deionized water, ozonated deionized water, an ammonia aqueous solution, hydrochloric acid, sulfuric acid, hydrogen peroxide, or combinations thereof.

12. The method as claimed in claim 10, wherein the surface oxidation is performed at a temperature ranging from 50° C. to 75° C.

13. The method as claimed in claim 10, wherein the surface oxidation is performed for a time period ranging from 60 seconds to 200 seconds.

14. The method as claimed in claim 10, wherein the metal oxide layer and the metal silicate layer are removed by soaking the semiconductor structure in a chemical agent that includes hot deionized water, a mixture of hydrochloric acid, hydrogen peroxide and deionized water, dilute hydrochloric acid, or carbonated deionized water.

15. A method for manufacturing a semiconductor device, comprising:
forming a semiconductor structure on a semiconductor substrate, the semiconductor structure including
a first source/drain region and a second source/drain region which are disposed on the semiconductor substrate in a first direction normal to the semiconductor substrate and which are spaced apart from each other in a second direction transverse to the first direction, and
a plurality of channel features which are disposed between and connected to the first source/drain region and the second source/drain region and which are spaced apart from one another in the first direction;
forming an interfacial material layer to cover each of the plurality of channel features;
forming a metal oxide layer on the interfacial material layer;
subjecting the interfacial material layer and the metal oxide layer to thermal treatment, so as to form a metal silicate layer and a plurality of interfacial features respectively covering the plurality of channel features, the metal silicate layer being formed between the metal oxide layer and each of the plurality of interfacial features; and
removing the metal oxide layer and the metal silicate layer.

16. The method as claimed in claim 15, wherein the thermal treatment is performed at a temperature ranging from 500° C. to 800° C.

17. The method as claimed in claim 15, wherein the thermal treatment is performed for a time period ranging from 10 seconds to 600 seconds.

18. The method as claimed in claim 15, wherein the thermal treatment is an annealing treatment.

19. The method as claimed in claim 15, wherein a thickness difference between the interfacial material layer and each of the interfacial features ranges from 4 Å to 10 Å.

20. The method as claimed in claim 15, further comprising, after removal of the metal oxide layer and the metal silicate layer, forming a plurality of gate dielectric features, each of which covers the interfacial features and includes magnesium oxide, calcium oxide, aluminum oxide, zirconium silicate, scandium oxide, or combinations thereof.
